(19) United States
(12) Patent Application Publication
(10) Pub. No.: US 2011/0067909 A1
(43) Pub. Date: Mar. 24, 2011

(54) Embedded Circuit Board Structure and Fabrication Process Thereof

(76) Inventor: Wei-Ming Cheng, Taoyuan City (TW)

(21) Appl. No.: 12/787,422

(22) Filed: May 26, 2010

(30) Foreign Application Priority Data
Sep. 23, 2009 (TW) 098132157

(51) Int. Cl. H05K 1/09; H05K 1/00

(52) U.S. Cl. 174/257; 174/250; 174/258

(57) ABSTRACT

An embedded circuit board structure and a fabricating process thereof are disclosed. The embedded circuit board structure comprises a dielectric layer and a metal layer. The dielectric layer comprises an indentation; the indentation is formed by a plurality of pits, and the pits are substantially perpendicular to the surface of the dielectric layer. The metal layer is formed within the indentation.

### BACKGROUND OF THE INVENTION

1. Field of the Invention

The present invention relates to an embedded circuit board structure and fabrication process thereof, and more specifically, addresses the surface unevenness problem during the electroplating process of a large copper surface area.

2. Description of the Related Art

With rapid advances in the electronics industry, electronic devices are required to be miniaturized; therefore, the volume of the circuit board is reduced and more electronic units are installed per unit volume of the circuit board. However, the contact area between the wire and the circuit board is reduced as the circuit size is reduced; as a result, the adhesiveness between the wire and the circuit board is weakened and could be detached, thus causing the electronic product to malfunction. This degrades the product reliability. To address the abovementioned problem, an embedded circuit board structure is developed. This development is able to address the contact problem between the wire and the circuit board, and it can also reduce the overall volume of the circuit board in order to miniaturize electronic products.

However, during the fabrication process of an embedded circuit board, the cladding material formed from electroplating is unevenly disposed onto the circuit line and the large surface area. The large surface area must be electroplated for a longer period to form a large copper surface, whereas the circuit line needs to be electroplated only for a short duration. Therefore, the electroplating process of the large copper surface area and the circuit line cannot be concurrently completed. FIG. 1 and FIG. 2 show the electroplating process for producing a large copper surface and illustrates the problem of surface unevenness that occurs in the prior art. As shown in FIG. 1, an embedded circuit board structure 1a of the prior art consists of a dielectric layer 11a; dielectric layer 11a comprises an embedded circuit groove 112a and an indentation 111a, wherein the surface area of indentation 111a is larger than the circuit groove 112a. As shown in FIG. 2, during the electroplating process of the circuit groove 112a and the indentation 111a, the circuit groove 112a may be completely electroplated before the indentation 111a, forming a circuit layer 14a; as a result, the indentation 111a may be incompletely electroplated, forming an uneven metal layer 12a which is lower at the center and has a higher perimeter.

Therefore, an embedded circuit board structure and a fabrication process thereof must be provided to address the abovementioned problem.

### SUMMARY OF THE INVENTION

The object of the present invention is to provide an embedded circuit board structure and a fabrication process thereof, whereby a copper layer can be efficiently and evenly formed onto a large surface indentation during an electroplating process.

The embedded circuit board structure comprises a dielectric layer and a metal layer. The dielectric layer comprises an indentation; the indentation is formed by a plurality of pits, and the pits are substantially perpendicular to the surface of the dielectric layer. The metal layer is formed within the indentation.

In one embodiment, the dielectric layer further comprises at least one circuit groove, and the at least one circuit grooves form the circuit layer. The surface area of the metal layer is greater than the surface area of the circuit layer.

In one embodiment, the metal layer can be copper or a copper compound. In one embodiment of the present invention, the indentation has the largest diameter; it is substantially not less than 100 μm. In one embodiment, the top width of the pit is substantially not more than 50 μm. In one embodiment, the depth of the pit is substantially not more than 50 μm.

The embedded circuit board structure and a fabricating process thereof comprise the following steps: providing a dielectric layer; forming an indentation on the dielectric layer, the indentation being formed by a plurality of pits, and the pits being substantially perpendicular to the surface of the dielectric layer; forming the circuit grooves on the dielectric layer; and forming a metal layer and a circuit layer within the indentation and the circuit grooves, respectively.

In one embodiment, the indentation and plurality of pits of the dielectric layer are produced through a laser process.

### BRIEF DESCRIPTION OF THE DRAWINGS

FIG. 1 shows an embedded circuit board structure of the prior art.

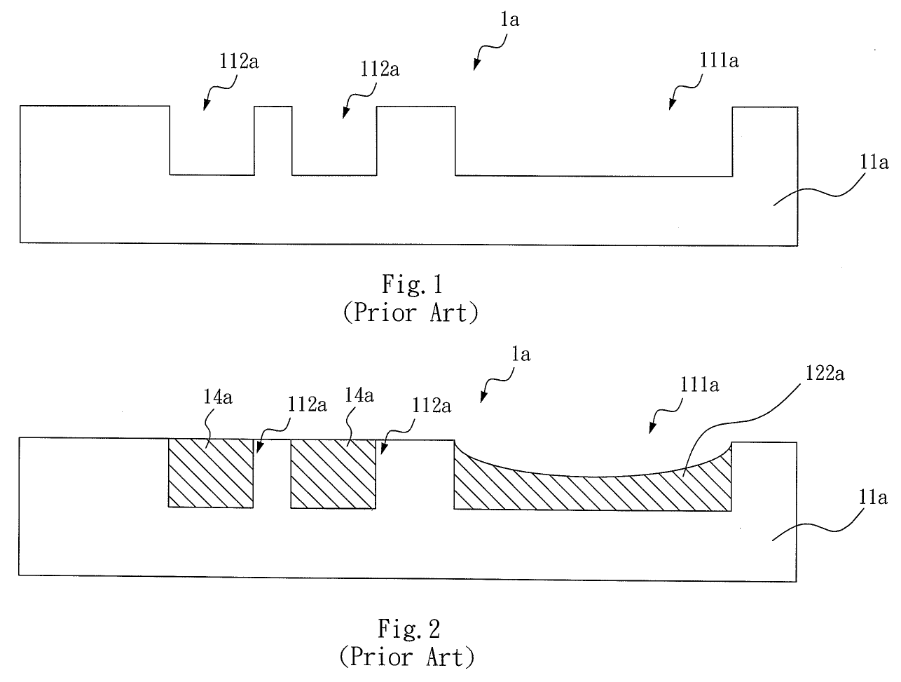

FIG. 2 shows the unevenness of the metal layer during the electroplating process of an embedded circuit board in relation to the prior art.

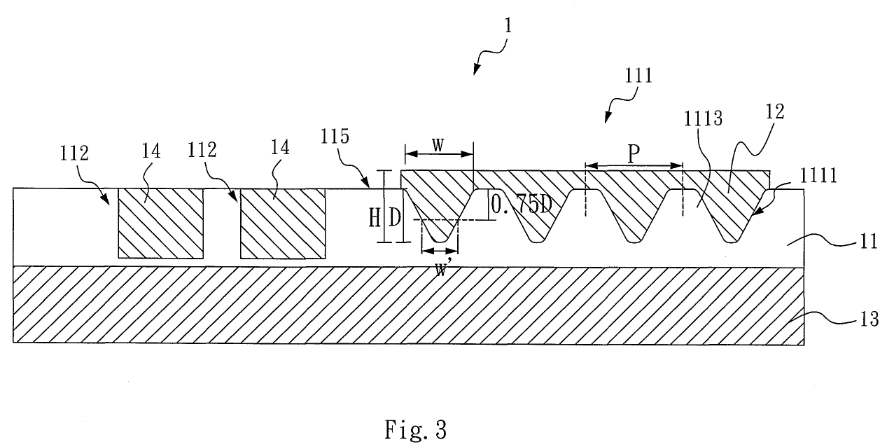

FIG. 3 shows a cross-sectional view of an embedded circuit board structure.

FIG. 4 shows the position of the pits in relation to the dielectric layer surface.

FIG. 5 is an oblique view of an embedded circuit board structure before the metal layer is formed.

FIG. 6 shows a top view of an indentation of another embodiment.

FIG. 7 is a flow chart which shows the method of producing an embedded circuit board structure.

FIG. 8 to FIG. 10 are flow charts which show the method of producing an embedded circuit board structure.

### DETAILED DESCRIPTION OF THE PREFERRED EMBODIMENT

The advantages and innovative features of the invention will become more apparent from the following preferred embodiments.

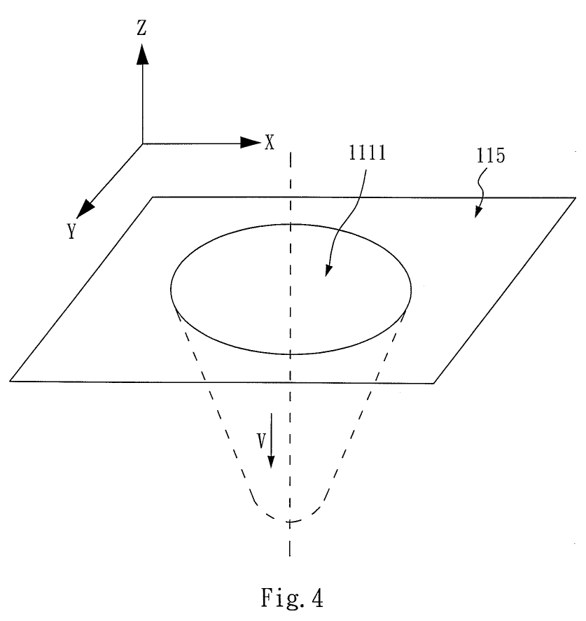

Refer to FIG. 3 to FIG. 6 for one embodiment of the embedded circuit board structure. Take note that these figures are simplified to illustrate the concept of the embedded circuit board structure. The number of elements, shape, and size ratio can be different from the actual implementation, wherein the element layout can be more intricate.

As shown in FIG. 3, an embedded circuit board structure 1 comprises a substrate 13, a dielectric layer 11, a metal layer 12, and a circuit layer 14. Whereas the method of forming the dielectric layer 11 onto the substrate 13 is a known skill and is not the primary focus of the present invention, it will not be discussed further. In any of the embodiments herein, the substrate 13 can be a single layer or a plurality of layers of a printed circuit board consisting of patterned circuits, or an embedded circuit board; however, the present invention is not only limited to this circuit formation. Take note that substrate 13 is not an essential element of the present invention.

In one embodiment of the present invention, the dielectric layer 11 is composed from at least one of the following materials: Ajinomoto Build-up Film; Bismaleimide Triazine (BT); benzocylobutene (BCB); liquid crystal polymer; polyimide (PI); polyphenylene ether; polytetrafluoroethylene; aramide; epoxy resins and glass fiber. However, the present invention is not limited only to these materials.

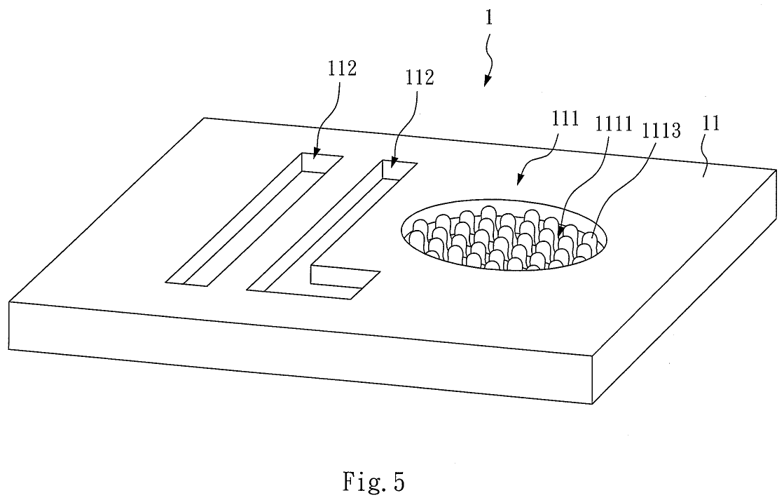

As shown in FIG. 3, the dielectric layer 11 comprises an indentation 111 and circuit grooves 112. The indentation 111 is formed by the plurality of pits 1111, and these pits are substantially perpendicular to the dielectric layer surface 115. FIG. 4 shows the position of these pits 1111 in relation to the dielectric layer surface 115. The dielectric layer surface 115 lies on the plane surface constructed by the X and the Y axis; the direction of the V shape formed by these pits 1111 substantially runs along the Z axis; therefore, the plurality of pits 1111 are substantially perpendicular to the dielectric layer surface 115, but the present invention is not limited to the above-mentioned configurations. Take note that in order to simplify the description, FIG. 4 shows only one pit 1111 and a small portion of the dielectric layer surface 115.

Take note that the indentation 111 provides the location for the formation of a metal layer 12 with a larger surface area. The surface area of the metal layer 12 is greater than the surface area of each circuit layer 14; therefore, the surface area of indentation 111 is greater than the surface area of each circuit groove 112; the details relating to the surface area of the indentation 111 will be described in the subsequent section.

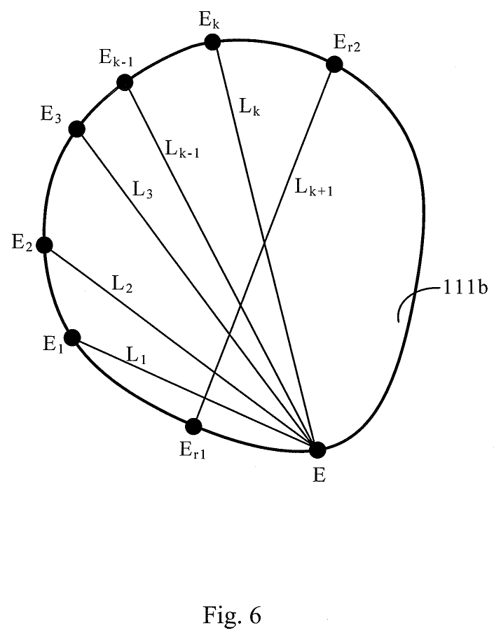

In one embodiment, the indentation 111 and the plurality of pits 1111 of the dielectric layer 11 are created with a laser process. The surface area for the formation of the metal layer 12 is heat-engraved to produce the plurality of pits 1111, thus forming the indentation 111 in the dielectric layer 11. However, the present invention is not limited to the aforementioned method. FIG. 5 is an oblique view of the embedded circuit board structure 1 before the formation of the metal layer 12. Take note that as shown in FIG. 3 or FIG. 5, the un-engraved section of the dielectric layer 11 forms pillars 1113 in the indentation 111. In one embodiment, the method of forming the circuit grooves 112 in the dielectric layer 11 is known as the circuit patterning technique, but the present invention is not limited to this process. The circuit patterning technique includes the steps of surface cleaning, photoresist coating, light exposure, developing, etching, and removing the photoresist coating. Whereas the circuit patterning technique is a known skill and is not the primary focus of the present invention, it will not be discussed further.

In one embodiment, as shown in FIG. 3, these pits 1111 are formed in a circular shape, but the present invention is not limited to this shape. For example, depending on the process requirements, these pits 1111 produced with laser engraving can take on the shape of a trapezium, a cone, a pillar, or a cube, and its size can be varied accordingly.

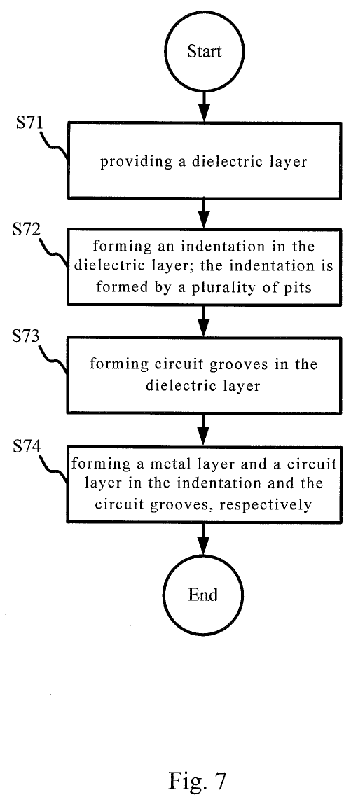

In one embodiment, the maximum diameter of the indentation 111 is substantially not less than 100 μm. FIG. 6 shows a top view of an indentation of another embodiment, and these pits are excluded to simplify the description of the maximum diameter. The maximum diameter is determined by the following method: selecting any point on the perimeter of indentation 111b as a starting point E, and measuring the distance to a plurality of points E₁, E₂, E₃ . . . Eₖ₋₁ and Eₖ which are located on the perimeter of the indentation 111, then obtaining the corresponding distance L_{I}, L₂, L₃ . . . Lₖ₋₁ and Lₖ, wherein Lₖ>Lₖ₋₁. Under the condition when the distance Lₖ₊₁ between two other arbitrary points Eᵣ₁ and Eᵣ₂ can no longer exceed Lₖ, then the maximum diameter of the indentation 111 Lₖ is obtained. Take note that the method of determining the maximum diameter is not limited to the shape shown in FIG. 6. This method can be applied to any arbitrary shape.

In one embodiment, as shown in FIG. 3, the top width W of these pits 1111 is substantially not more than 50 μm; the depth D of these pits 1111 is substantially not more than 50 μm; moving down three quarters of the depth D from the dielectric layer surface 115, the bottom width W′ of these pits 1111 is substantially not more than 50 μm; and the distance P between each pit 1111 is substantially one eighth to nine sixth of the bottom width W′.

In a preferred embodiment, the top width W of these pits 1111 is substantially not more than 30 μm; the depth D of these pits 1111 is substantially not more than 30 μm; moving three quarters down the depth D from the dielectric layer surface 115, the bottom width W′ of these pits 1111 is substantially not more than 30 μm; and the distance P between each pit 1111 is substantially one seventh and nine seventh of the bottom width W′.

The metal layer 12 is formed on the plurality of pits 1111 of the indentation 111. In one embodiment, the metal layer 12 and the circuit layer 14 are made of copper or copper compound, but the present invention is not limited to these materials. In one embodiment, the method of electroplating or chemical plating is used in forming the metal layer 12 and the circuit layer 14 onto the indentation 111 and the circuit groove 112, respectively. However, the present invention is not limited to the abovementioned method. Please note that, as shown in FIG. 3, the thickness H of the metal layer 12 is substantially greater than the depth D of these pits 1111 in order for the metal layer 12 to form a flat surface on top of the indentation 111, such that it can be used as a circuit or as an electric conductor between other electronic units.

Take note that the metal layer 12 needs to be electroplated only inside the plurality of pits 1111 of the indentation 111; therefore, the metal layer 12 could be formed efficiently and evenly inside the indentation 111. This method is able to resolve the unevenness problem during the fabrication of a large-surfaced metal layer and a small-surfaced circuit layer. In one embodiment, the thickness H of the metal layer 12 and the distance P between each pit 1111 has the following relationship: the thickness H decreases as the distance P increases.

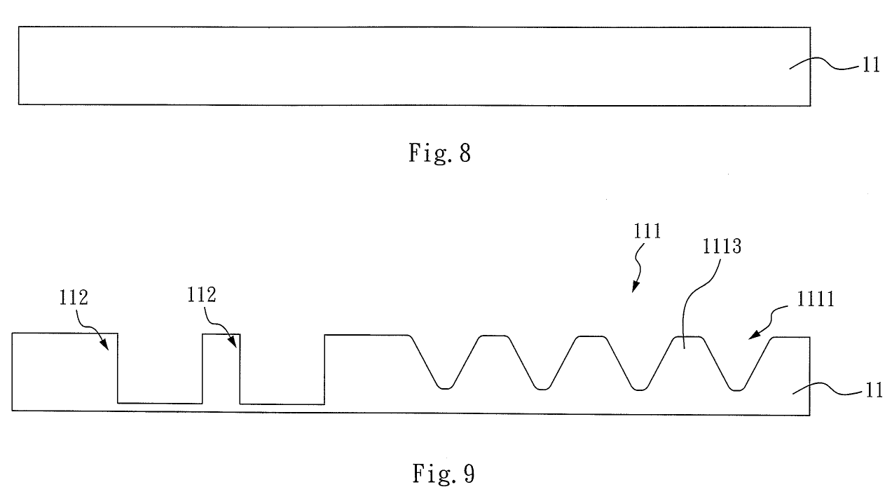

Next, refer to FIG. 7 to FIG. 10 for flow charts that show the method of fabricating an embedded circuit board structure.

As shown in FIG. 7, the present invention proceeds with step S71: providing a dielectric layer.

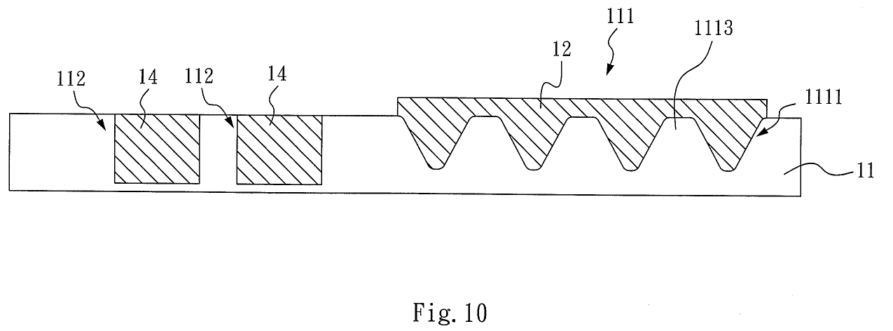

In one embodiment of the present invention, as shown in FIG. 8, the dielectric layer 11 is composed from at least one of the following materials: Ajinomoto Build-up Film (ABF); Bismaleimide Triazine (BT); benzocylobutene (BCB); liquid crystal polymer; polyimide (PI); polyphenylene ether; polytetrafluoroethylene; aramide; epoxy resins and glass fiber. However, the present invention is not limited only to these materials.

Next proceed to step S72: forming an indentation in the dielectric layer; the indentation is formed by a plurality of pits.

In one embodiment as shown in FIG. 9, the indentation 111 and the plurality of pits 1111 of the dielectric layer 11 are created with a laser process wherein the area for producing the metal layer is heat-engraved to produce the plurality of pits 1111, thus forming the indentation 111 in the dielectric layer 11. However, the present invention is not limited to this method. Take note that the indentation 111 is used for the formation of the large-surfaced metal layer. The un-engraved section of the dielectric layer 11 forms pillars 1113 in the indentation 111.

The maximum diameter of the indentation 111 and the shape and size of the pits 1111 have already been mentioned, and will not be further discussed.

Next, proceed to step S73: forming circuit grooves in the dielectric layer.

In one embodiment, as shown in FIG. 9, the method of forming circuit grooves 112 in the dielectric layer 11 is known as the circuit patterning technique, but the present invention is not limited to this process. The circuit patterning technique includes the steps of surface cleaning, applying photoresist coating, light exposure, developing, etching, and removing the photoresist coating. Whereas circuit patterning technique is a known skill and it is not the primary focus of the present invention, it will not be discussed further.

Last, proceed to step S74: forming a metal layer and a circuit layer in the indentation and the circuit grooves, respectively.

In one embodiment, as shown in FIG. 10, the metal layer 12 and the circuit layer 14 are made of copper or copper compound, but the present invention is not limited to these materials. In one embodiment, the method of electroplating or chemical plating is used in forming the metal layer 12 and the copper wire 14 onto the indentation 111 and the circuit grooves 112, respectively. However, the present invention in not limited to the abovementioned method.

Take note that knowledgeable users with experience in this field can alter the sequence of the above steps or execute some of the steps simultaneously to achieve the same result.

Although the present invention has been explained in relation to its preferred embodiment, it is also of vital importance to acknowledge that many other possible modifications and variations can be made without departing from the spirit and scope of the invention as hereinafter claimed.

What is claimed is:

1. An embedded circuit board structure comprising:
a dielectric layer, the dielectric layer comprising:
an indentation, wherein the indentation is formed by a plurality of pits, wherein the pits are substantially perpendicular to a dielectric surface layer of the dielectric layer; and
a metal layer, wherein the metal layer is formed within the indentation.

2. The embedded circuit board structure as claimed in claim 1, wherein the dielectric layer further comprises:
at least one circuit groove, and the at least one circuit grooves form a circuit layer, wherein the surface area of the metal layer is greater than the surface area of the circuit layer.

3. The embedded circuit board structure as claimed in claim 2, wherein the circuit layer is formed of copper or a copper compound, wherein the metal layer is formed of copper or a copper compound.

4. The embedded circuit board structure as claimed in claim 2, wherein the indentation has a largest diameter, wherein the diameter is substantially not less than 100 μm.

5. The embedded circuit board structure as claimed in claim 2, wherein a top width of the pit is substantially not more than 50 μm.

6. The embedded circuit board structure as claimed in claim 2, wherein a depth of the pit is substantially not more than 50 μm.

7. The embedded circuit board structure as claimed in claim 6, wherein moving three quarters down the depth from the surface of the dielectric layer, the bottom width is substantially not more than 50 μm.

8. The embedded circuit board structure as claimed in claim 7, wherein the distance of each pit is substantially between one eighth to nine sixth of the bottom width.

9. The embedded circuit board structure as claimed in claim 8, wherein the thickness of the metal layer is greater than the depth.

10. The embedded circuit board structure as claimed in claim 9, wherein the thickness of the metal layer and the distance of each pit have the following relationship: The thickness decreases as the distance increases.

11. The embedded circuit board structure as claimed in claim 1, wherein the embedded circuit board structure further comprises a substrate, wherein the dielectric layer is formed on the substrate.

12. The embedded circuit board structure as claimed in claim 11, wherein the substrate is a single layer or a plurality of layers of a printed circuit board consisting of patterned circuits, or an embedded circuit board.

13. The embedded circuit board structure as claimed in claim 1, wherein the dielectric layer is composed from at least one of the following materials: Ajinomoto Build-up Film (ABF); Bismaleimide Triazine (BT); benzocylobutene (BCB); liquid crystal polymer; polyimide (PI); polyphenylene ether; polytetrafluoroethylene; aramide; epoxy resins and glass fiber.

14. An embedded circuit board structure fabricating method comprising the following steps:
providing a dielectric layer;
forming an indentation on the dielectric layer, wherein the indentation is formed by a plurality of pits, wherein the pits are substantially perpendicular to a dielectric surface layer of the dielectric layer; and
forming a metal layer in the indentation.

15. The embedded circuit board structure fabricating method as claimed in claim 14 further comprising the following steps:
forming a circuit groove in the dielectric layer; and
forming a circuit layer in the circuit groove.

16. The embedded circuit board structure fabricating method as claimed in claim 15, wherein the indentation and the plurality of pits of dielectric layer are created with a laser forming process.

17. The embedded circuit board structure fabricating method as claimed in claim 15; the metal layer is formed of copper or a copper compound, wherein the circuit layer is formed of copper or a copper compound.

18. The embedded circuit board structure fabricating method as claimed in claim 15, wherein a method of electroplating or chemical plating is used in forming the metal layer into the indentation.

19. The embedded circuit board structure fabricating method as claimed in claim 15, wherein the thickness of the metal layer is greater than the depth of the pit.

20. The embedded circuit board structure fabricating method as claimed in claim 19, wherein the thickness of the metal layer and the distance of each pit have the following relationship: The thickness decreases as the distance increases.
